(19) United States
(12) Patent Application Publication
(10) Pub. No.: US 2007/0259541 A1
(43) Pub. Date: Nov. 8, 2007

(54) Electrical interconnection device having dielectric coated metal substrate

(75) Inventors: Marjorie Kay Myers, Mount Wolf, PA (US); Charles Randall Malstrom, Lebanon, PA (US); Andrew Dewitt Balthaser, Dauphin, PA (US); Michael F. Laub, Harrisburg, PA (US); Lewis Brian Lerner, Harrisburg, PA (US); Attalee S. Taylor, Palmyra, PA (US)

Correspondence Address: Robert J. Kalpalka;Tyco Technology Resources, Suite 140, 4550 New Linden Hill Road, Wilmington, DE, 19808-2952, US

(73) Assignee: Tyco Electronics Corporation

(21) Appl. No.: 11/429,800

(22) Filed: May 8, 2006

(51) Int. Cl. H05K 1/00

(52) U.S. Cl. 439/70

(57) ABSTRACT

A electrical interconnection device for receiving and holding a plurality of electrical contacts. The electrical interconnection device includes a metal support substrate having an array of contact receiving apertures extending therethrough. Each of the contact receiving apertures is defined by an aperture wall and the contact receiving apertures are adapted to receive the plurality of electrical contacts. The electrical interconnection device also includes a dielectric layer coating the aperture wall. The dielectric layer insulates the plurality of electrical contacts from the substrate.

### BACKGROUND

The present invention relates to electrical interconnection devices having a metal substrate for holding contacts, and to methods for making such interconnection devices.

Electrical interconnection devices are used to electronically couple components, such as a microprocessor, to a printed circuit board. Typical interconnection devices use multiple metal contacts to transmit electronic signals between the components. Increasing the rate of transmission and decreasing the overall size of the interconnection devices have been ongoing goals of the industry.

To improve the rate of transmission of these electronic signals efforts have been made to increase the density of the connections within the interconnection device. In some interconnection devices, injection molded plastic housings are used to receive and support a plurality of electrical contacts. However, the True Position (TP), geometry and co-planarity across the plastic housings are limited by the response and variability of the polymer to the injection molding process. In addition, such plastic housings may be susceptible to shrinkage, warping, bowing and bending. Also, it is beneficial to shield the signal contacts from one another and prevent cross-talk therebetween. However, while these plastic housing structures may isolate the metal contacts from one another, they do not provide shielding. To shield the signal contacts and provide a larger ground path than is typically available in such non-conductive connectors, the plastic housing structures may be metallized or may be equipped with ground planes. Nevertheless, it may be difficult to manufacture plastic housings that meet the demands for increasingly small connectors. The thin walls separating the contacts may be weak and susceptible to breakage.

As disclosed in disclosed in U.S. Pat. No. 6,945,788 to Trout et al., rigid metal substrate structures have been proposed as an alternative to the plastic housings for supporting the signal contacts. These metal substrate structures may be sized to fit within a plastic housing and include a plurality of apertures sized to receive the signal contacts. The metal substrate structure provides a rigid substrate that is resistant to shrinkage. To insulate the signal contacts from one another and to secure the signal contacts within the apertures, each signal contact may be overmolded with an insulative plastic, which is swaged to the substrate. Although effective in insulating the signal contacts, the process of overmolding each individual signal contact adds time and expense to the manufacturing process. Accordingly, it is desirable to provide an electrical interconnection device that achieves high contact density in a robust package that is economical to produce.

### SUMMARY

The present invention provides connector apparatuses for interconnecting components and methods for making such connectors. In one form, the present invention provides an electrical interconnection device for receiving and holding a plurality of electrical contacts. The electrical interconnection device includes a metal support substrate having an array of contact receiving apertures extending therethrough. Each of the contact receiving apertures is defined by an aperture wall and the contact receiving apertures are adapted to receive the plurality of electrical contacts. The electrical interconnection device also includes a dielectric layer coating the aperture wall. The dielectric layer insulates the plurality of electrical contacts from the substrate and holds the contacts in position within the contact receiving apertures.

In one aspect of the above-described embodiment, the metal support substrate is formed of a plurality of metal layers stacked atop and bonded to one another. The dielectric layer may be formed of a dielectric, non-conductive material such as a plastic, a ceramic or glass. The dielectric coating may be applied in a liquid, solid or gas form to the apertures by any known technique, including for example, electrostatic fluidized bed, liquid dip coating, electrodeposition, vapor deposition, overmolding and spray coating.

In another form, the present invention provides a electrical interconnection device for connecting an electrical device to a circuit board. The electrical interconnection device includes a support substrate formed of metal and having a top surface and an opposing bottom surface. The support substrate includes a plurality of contact receiving apertures extending therethrough from the top surface to the bottom surface. Each of the plurality of contact receiving apertures is defined by an aperture wall. A dielectric layer coats the aperture wall and at least a portion of the top and bottom surfaces. A plurality of electrical contacts extend through the plurality of contact receiving apertures. The dielectric layer insulates the plurality of electrical contacts from the metal layers of the support substrate.

In yet another form, the present invention provides a method for manufacturing a electrical interconnection device. The method includes the steps of constructing a metal support substrate having a top surface and an opposing bottom surface, and forming a plurality of electrical contact receiving apertures extending through the metal support substrate from the top surface to the bottom surface. Each of the plurality of electrical contact receiving apertures is defined by an aperture wall. The method also includes the step of coating the aperture wall of each of the plurality of electrical contact receiving apertures with a dielectric composition.

The step of coating the aperture wall may include applying the dielectric composition in a liquid, powder or gas form to the apertures by a technique, such as electrostatic fluidized bed, liquid dip coating, electrodeposition, vapor deposition, overmolding and spray coating.

### BRIEF DESCRIPTION OF THE DRAWINGS

The above mentioned and other features and objects of this invention, and the manner of attaining them, will become more apparent and the invention itself will be better understood by reference to the following description of an embodiment of the invention taken in conjunction with the accompanying drawings, wherein:

FIG. 1 is a top view of a socket connector apparatus according to one embodiment of the present invention;

FIG. 2 is a side view of a socket connector apparatus of FIG. 1;

FIG. 3 is a partial, top sectional view of the socket connector apparatus of FIG. 2 taken along lines 3-3;

FIG. 4 is a partial, side sectional view of the socket connector apparatus of FIG. I taken along lines 4-4;

FIG. 5 is another partial, side sectional view of the socket connector apparatus of FIG. 1 taken along lines 5-5; and

FIG. 6 is a partial, side sectional view of a socket connector apparatus according to another embodiment of the present invention.

Corresponding reference characters indicate corresponding parts throughout the several views. Although the drawings represent embodiments of the present invention, the drawings are not necessarily to scale and certain features may be exaggerated in order to better illustrate and explain the present invention. Although the exemplification set out herein illustrates embodiments of the invention, in several forms, the embodiments disclosed below are not intended to be exhaustive or to be construed as limiting the scope of the invention to the precise forms disclosed.

### DETAILED DESCRIPTION

The embodiments hereinafter disclosed are not intended to be exhaustive or limit the invention to the precise forms disclosed in the following description. Rather the embodiments are chosen and described so that others skilled in the art may utilize its teachings.

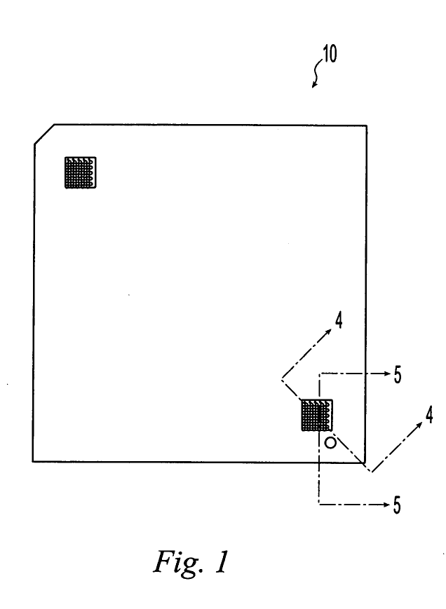

Referring to FIGS. 1-5, electrical interconnection device in the form of socket connector apparatus 10 according to one embodiment of the present invention will now be described. As illustrated in FIGS. 1-2 and 4-5 and described in further detail below, electrical interconnection device is in the form of ball grid array (BGA) socket connector apparatus 10 which may be used to interface or electronically couple a device, such as a microprocessor, with a circuit board. However, although the present invention is exemplified in the context of a BGA socket connector, the present invention is not limited to BGA socket connectors. Rather, the present invention may be adapted for use as any electrical interconnect structure, including, for example, a Land Grid Array (LGA) socket, Column Grid Array (CGA), right angle connectors and backplane connectors.

As illustrated in FIGS. 1-2 and 4-5, socket connector apparatus 10 generally includes support substrate 12 and electrical contacts 18 supported in support substrate 12. Support substrate 12 includes top surface 22, opposing bottom surface 24 and an array of contact receiving apertures 14 extending through substrate 12 from top surface 22 to bottom surface 24. Each of contact receiving apertures 14 is defined by aperture wall 20 and is sized to receive one of electrical contacts 18. Array of contact receiving apertures 14 may be arranged in any pattern and may include any number of apertures 14. Although the illustrative embodiment of FIGS. 1-5 show an array of contact receiving apertures, support substrate 12 may include a single contact receiving aperture.

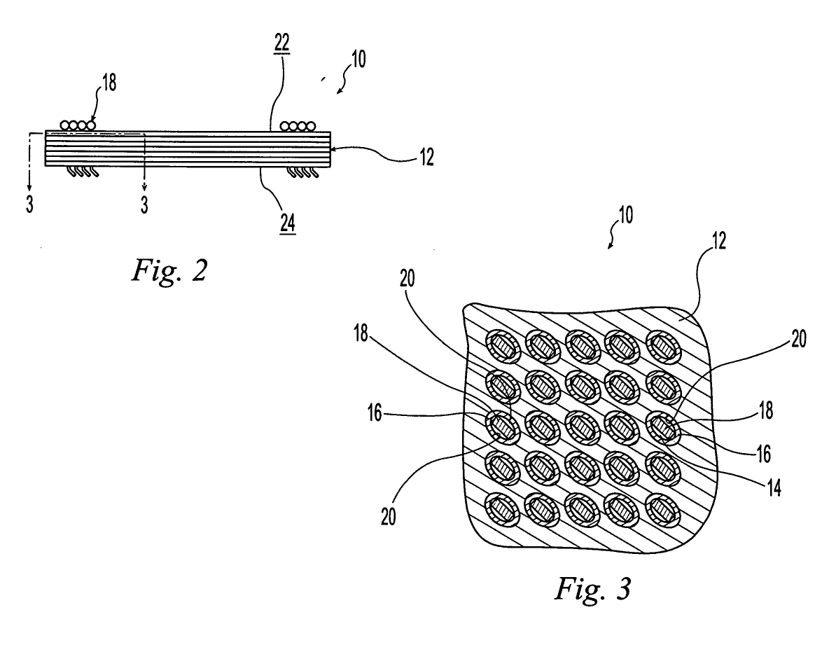

Turning now to FIGS. 2 and 4-5, support substrate 12 is formed of a plurality of metal layers or sheets 26a-26g stacked atop and bonded to one another by any suitable method including, for example, that disclosed in U.S. Patent Application Publication No. 2005/0221634, filed as U.S. patent application Ser. No. 10/818,038 on Apr. 5, 2004 in the names of Hilty et al., entitled Bonded Three Dimensional Metal Laminate Structure and Method, assigned to the assignee of the present invention and hereby incorporated by reference. Each of metal layers 26a-26g is formed of a rigid base metal such as copper, iron, steel, aluminum, tin, nickel, cobalt, titanium, zinc or alloys thereof. Each of metal layers 26a-26g may be formed of the same or different base metals. In some cases it may be beneficial for top layer 26a to be formed of a first metal, while bottom layer 26g is formed of a second different metal. For instance, when apparatus 10 is incorporated in a CGA device for connecting a chip to a circuit board, top layer 26a may be made of a metal, such as copper, to match the Coefficient of Thermal Expansion (CTE) of a circuit board, while the bottom layer 26g may be made of an alloy to match the CTE of a ceramic of the chip. Furthermore, in this particular embodiment, apparatus 10 may be composed of two parts that fit together; the first piece including top layer 26a and the second piece including bottom layer 26g.

Referring still to FIGS. 2 and 4-5, each of layers 26a-26g has a thickness t, which may vary depending on the application. For instance, in one exemplary embodiment, thickness t of each of layers 26a-26g is between about 0.1 mm and 0.3 mm and, therefore, metal substrate 12 has an overall thickness T of between about 0.7 mm and 2.1 mm. Each of layers 26a-26g includes an array of apertures, which cooperate with one another when layers 26a-26g are properly aligned and stacked atop one another to form contact receiving apertures 14. Each of layers 26a-26g may include alignment features such as indents, slots, points, pips, barbs or apertures (not shown) to facilitate the proper alignment and stacking of layers 26a-26g. Layers 26a-26g may be formed by known means including, for example, chemical etching or die stamping.

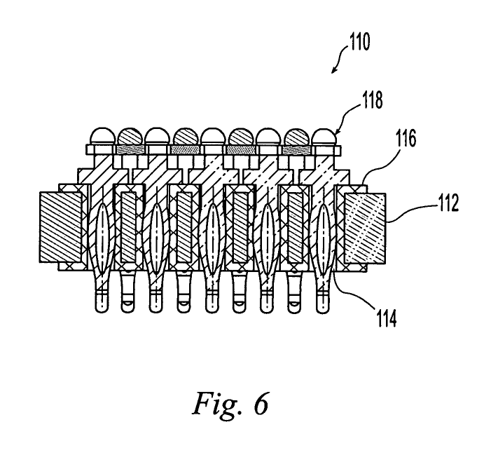

It should be understood that, although support substrate 12 is illustrated as having seven metal layers 26a-26g, the support substrate of the present invention may have any number of layers. Further, each of layers 26a-26g need not be of equal thickness, but may vary in thickness. In addition, the overall thickness of substrate 12 may vary. It should also be understood that support substrate 12 may be formed of a single metal layer, rather than a laminate of multiple metal layers, as shown in FIG. 6 and discussed in further detail below. In addition, each metal layer need not be of the same geometry. Rather, the layers could include various geometrical variations such as steps, shoulders, pockets or holes. In addition, support substrate, particularly top and bottom surfaces 22, 24 and/or aperture wall 20 of apertures 14, may include barbs, ridges, bumps or other surface texture features to assist in the binding of dielectric layer 16 to support substrate 12.

Referring still to FIGS. 3-5, socket connector apparatus 10 also includes dielectric layer 16, which coats and insulates aperture wall 20. Dielectric layer 16 may also extend outwardly from aperture 14 to coat all or a portion of top and bottom surfaces 22, 24 of support substrate 12. Dielectric layer 16 is formed of a dielectric material capable of insulating metal support substrate 12 from contact 18 disposed in aperture 14. As discussed in further detail below, the dielectric material should also be durable enough to resist penetration by contact 18 when contact 18 is loaded into aperture 14. Suitable dielectric materials may include ceramics, glass and plastics, including both thermoset polymers and thermopolymers. Suitable dielectric materials may be in any form including powder, liquid and/or gas and, if necessary, may be cured using any suitable means, such as heat, radiation and catalysts. For example, thermoplastic resin powder coatings suitable for use as a dielectric material may include polyamide, polyester, polyether-ether-ketone (PEEK), polypropylene, polyethylene and fluoropolymers. In one particular embodiment, the dielectric material is Scotchcast™ Electrical Resin 5230N, an epoxy resin available from 3M of St. Paul, Minn. Additional examples of suitable commercially available thermoplastic powder coating materials include Rohm & Haas polyamides and polyesters, Victrex PEEK, and Hyflon fluoropolymers from Solvay Solexis. Examples of suitable commercially available thermosetting powder coatings include Stator Red epoxy from DuPont, Resicoat epoxy from Akzo Nobel, Mor-Temp silicone from Morton International, and Torlon polyamide-imide from Solvay.

The dielectric material may be applied to support substrate 12 using any suitable coating techniques including, for example, electrostatic fluidized bed methods, liquid dip coating methods, electrodeposition methods, vapor deposition methods, overmolding and spray coating. In one particular embodiment, the Scotchcast™ Electrical Resin 5230N is applied using an electrostatic fluidized bed method. Dielectric layer 16 has a thickness t_{d}, which may vary depending on the size and structure of contact 18 and aperture 14. In one particular embodiment, dielectric layer 16 has a thickness t_{d} of between about 0.075 mm to 0.125 mm (0.003 inches-0.005 inches).

As suggested above, the dielectric material may be applied to aperture wall 20 of each of apertures 14 such that dielectric layer 16 coats aperture wall 20. The dielectric material may also be applied to a portion of top and/or bottom surfaces 22, 24 of support substrate 12 proximal apertures 14 to provide further insulation between contact 18 and metal support substrate 12. The efficiency of the manufacture of connector apparatus 10 may be further improved by avoiding the selective application of the dielectric material to aperture wall 20 and a portion of top and bottom surfaces 22, 24 and, instead, applying the dielectric material to all exposed surfaces of support substrate 12 including aperture wall 20 and top and bottom surfaces 22, 24. It should be understood that aperture wall 20 of every one of the plurality of apertures 14 need not be coated. For instance, it may be desirable to only coat a selected one or few of apertures 14, in which case, those apertures 14 not requiring dielectric layer 16 may be plugged during the application of the dielectric material.

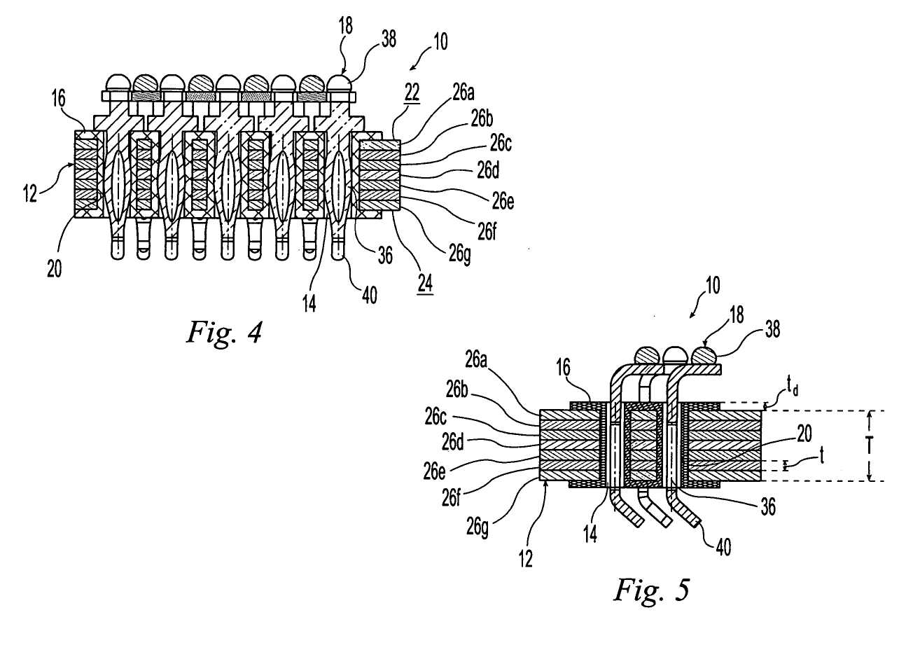

Referring now to FIGS. 4-5, each of contacts 18 are formed of a conductive metal such as copper, iron, steel, aluminum, tin, nickel, cobalt, titanium, zinc or alloys thereof. Each of contacts 18 includes resilient body portion 36, which is configured to fit within coated aperture 14 and is adapted to bias outwardly against aperture wall 20 to thereby hold body 36 within aperture 14 by interference fit. More specifically, body 36 is in the form of an eye-of-the-needle contact. Each of contacts 18 also include upper ball contact 38 extending from one end of body 36 and protruding from aperture 14 proximal top surface 22 of support substrate 12. Lower pin contact 40 extends from the end of body 36 opposite upper contact 38 and protrudes from aperture 14 proximal bottom surface 24 of support substrate 12. Although contacts 18 of the exemplary embodiment are illustrated in FIGS. 1-6 and described above as eye-of-the-needle ball contacts, the present invention may employ any known contact design.

Contacts 18 are directly loaded into coated apertures 14 by inserting lower pin contact 40 through, and forcing body 36, into aperture 14. As body 36 is positioned in aperture 14, body 36 biases and scrapes against dielectric layer 16, but does not penetrate dielectric layer 16. Once inserted into aperture 14, body 36 is held by interference fit against dielectric layer 16 in aperture 14.

Metal support substrate 12 provides connector apparatus 10 with a rigid and stable support structure that resists bending and bowing, while dielectric layer 16 insulates contact 18 from metal support substrate 12. Dielectric layer 16 also eliminates the need for overmolding or coating contacts 18 prior to loading in apertures 14, and allows contact 18 to be directly loaded into apertures 14.

Turning now to FIG. 6, connector apparatus 110 according to another embodiment of the present invention is illustrated. Connector apparatus 110 includes support substrate 112, which is formed of a single metal layer rather than multiple layers. Apertures 114 extend through substrate 112 and receive contacts 118. Apertures 114 are coated with dielectric layer 116 as described above with respect to connector apparatus 10. The single metal layer of support substrate 112 may be formed by known means including, for example, chemical etching or die stamping.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. An electrical interconnection device for receiving a plurality of electrical contacts, the electrical interconnection device comprising:
a support substrate having an array of contact receiving apertures extending therethrough, each of said contact receiving apertures being defined by an aperture wall, said array of contact receiving apertures adapted to receive the plurality of electrical contacts; and
a dielectric layer coating said aperture wall for insulating the plurality of electrical contacts from said substrate.

2. The electrical interconnection device of claim 1 wherein said metal support substrate includes a plurality of metal layers stacked atop and bonded to one another.

3. The electrical interconnection device of claim 1 wherein at least one of said plurality of metal layers is formed of a first metal and at least one of said plurality of metal layers is form of a second metal, said first metal having a different composition than said second metal.

4. The electrical interconnection device of claim 1 wherein said dielectric layer comprises a plastic.

5. The electrical interconnection device of claim 1 wherein said dielectric layer comprises a ceramic.

6. The electrical interconnection device of claim 1 wherein said dielectric layer is a cured dry powder coating.

7. The electrical interconnection device of claim 1 wherein said dielectric layer is a cured liquid dip coating.

8. A electrical interconnection device comprising:
a support substrate formed of metal and having a top surface and an opposing bottom surface, said support substrate including at least one contact receiving aperture extending therethrough from said top surface to said bottom surface, each of said at least one contact receiving aperture being defined by an aperture wall;
a dielectric layer coating said aperture wall; and
an electrical contact disposed in said at least one contact receiving aperture, said dielectric layer insulating said electrical contact from said metal.

9. The electrical interconnection device of claim 8 wherein said support substrate includes a plurality of etched metal layers stacked atop one another.

10. The electrical interconnection device of claim 8 wherein said dielectric layer comprises a plastic.

11. The electrical interconnection device of claim 8 wherein said dielectric layer comprises a ceramic.

12. The electrical interconnection device of claim 8 wherein said dielectric layer coats at least a portion of said top and bottom surfaces.

13. The electrical interconnection device of claim 8 wherein said support substrate includes surface texture features.

14. The electrical interconnection device of claim 8 wherein each of said plurality of electrical contacts includes a biasing body portion and a contact portion extending from said body portion, said biasing body portion is held by interference fit against said dielectric layer within said plurality of contact receiving apertures.

15. A method for manufacturing a electrical interconnection device comprising the steps of:
constructing a metal support substrate having a top surface and an opposing bottom surface;
forming a plurality of electrical contact receiving apertures extending through the metal support substrate from the top surface to the bottom surface, each of the plurality of electrical contact receiving apertures being defined by an aperture wall; and
coating the aperture wall of each of the plurality of electrical contact receiving apertures with a dielectric composition.

16. The method of claim 15 wherein said step of coating the constructed support substrate includes applying the dielectric composition using an electrostatic fluidized bed.

17. The method of claim 15 wherein said step of coating the constructed support substrate includes applying the dielectric composition using an electrodeposition technique.

18. The method of claim 15 further comprising the step of loading a contact member in at least one of the array of contact receiving apertures after the step of coating the constructed support member.

19. The method of claim 15 wherein said step of coating the aperture wall also includes coating at least a portion of the top and bottom surfaces of the support substrate with the dielectric composition.

20. The method of claim 15 wherein said dielectric composition comprises an epoxy powder resin.
